(19) United States
(12) Patent Application Publication
(10) Pub. No.: US 2024/0064976 A1
(43) Pub. Date: Feb. 22, 2024

(54) SEMICONDUCTOR ISOLATION DEVICE AND METHOD

(71) Applicant: Micron Technology, Inc., Boise, ID (US)

(72) Inventor: Michael Andrew Smith, Boise, ID (US)

(21) Appl. No.: 17/889,694

(22) Filed: Aug. 17, 2022

(51) Int. Cl. H01L 27/11526; G11C 16/04; H01L 27/11519; H01L 27/11524

(52) U.S. Cl. CPC H01L 27/11526; G11C 16/0483; H01L 27/11519; H01L 27/11524

(57) ABSTRACT

Apparatus and methods are disclosed, including transistors, semiconductor devices and systems with isolation structures. Example semiconductor devices and methods include isolation structures with tapered sidewalls that intersect along a line at a trench bottom. Example semiconductor devices and methods are shown with different isolation structures in peripheral circuitry compared to isolation structures in a memory array.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others. Non-volatile memory can retain stored data when not powered, and includes devices such as flash memory, read-only memory (ROM), electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

A storage system, such as a solid-state drive (SSD), can include a memory controller and one or more memory devices, including a number of dies or logical units (LUNs). In certain examples, each die can include a number of memory arrays and peripheral circuitry thereon, such as die logic or a die processor. The memory controller can include interface circuitry configured to communicate with a host device (e.g., the host processor or interface circuitry) through a communication interface (e.g., a bidirectional parallel or serial communication interface).

The present description relates generally to structures used in complementary metal oxide semiconductor (CMOS) devices and manufacture.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a memory device in accordance with some example embodiments.

FIG. 2 illustrates a top view of portions of a semiconductor memory device in accordance with some example embodiments.

FIG. 3 illustrates a cross section view of portions of the semiconductor memory device from FIG. 2 in accordance with some example embodiments.

FIG. 4 illustrates an example method flow diagram in accordance with other example embodiments.

FIG. 5 illustrates an example block diagram of an information handling system in accordance with some example embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

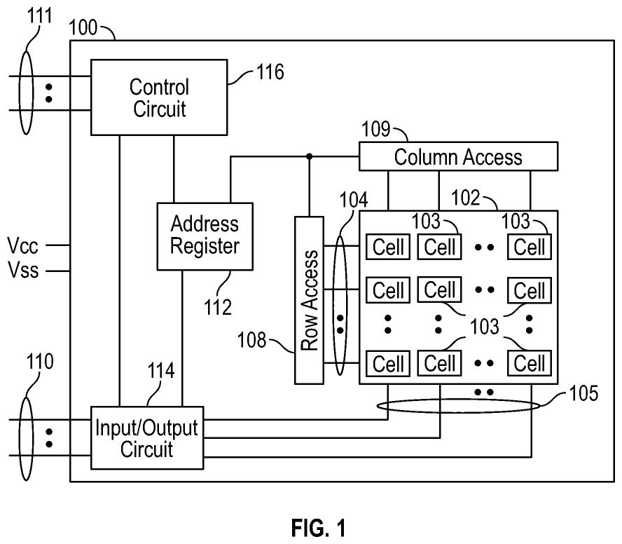

FIG. 1 shows a block diagram of an apparatus in the form of a memory device 100, according to an embodiment of the invention. Memory device 100 can include a memory array 102 having memory cells 103 that can be arranged in rows and columns along with lines (e.g., access lines) 104 and lines (e.g., data lines) 105. Memory device 100 can use lines 104 to access memory cells 103 and lines 105 to exchange information with memory cells 103.

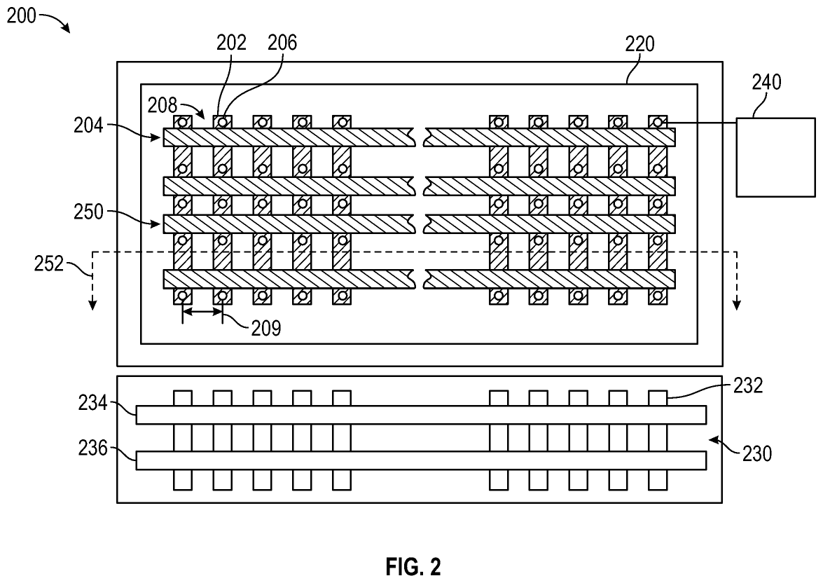

Memory cells 103 and other circuits 114, 116, etc. may include transistors and utilize methods as described in more detail in FIGS. 2-7. In one example, memory arrays 102 include NAND storage array, and peripheral circuits such as circuits 114, 116, 108, 109, etc. may include transistors as described in more detail in FIGS. 2-7.

Row access 108 and column access 109 circuitry can respond to an address register 112 to access memory cells 103 based on row address and column address signals on lines 110, 111, or both. A data input/output circuit 114 can be configured to exchange information between memory cells 103 and lines 110. Lines 110 and 111 can include nodes within memory device 100 or pins (or solder balls) on a package where memory device 100 can reside.

A control circuit 116 can control operations of memory device 100 based on signals present on lines 110 and 111. A device (e.g., a processor or a memory controller) external to memory device 100 can send different commands (e.g., read, write, or erase commands) to memory device 100 using different combinations of signals on lines 110, 111, or both.

Memory device 100 can respond to commands to perform memory operations on memory cells 103, such as performing a read operation to read information from memory cells 103 or performing a write (e.g., programming) operation to store (e.g., program) information into memory cells 103. Memory device 100 can also perform an erase operation to clear information from some or all of memory cells 103.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or an alternating-current to direct-current (AC-DC) converter circuitry.

Each of memory cells 103 can be programmed to store information representing a value of a fraction of a bit, a value of a single bit, or a value of multiple bits such as two, three, four, or another number of bits. For example, each of memory cells 103 can be programmed to store information representing a binary value “0” or “1” of a single bit. The single bit per cell is sometimes called a single level cell. In another example, each of memory cells 103 can be programmed to store information representing a value for multiple bits, such as one of four possible values “00,” “01,” “10,” and “11” of two bits, one of eight possible values “000,” “001,” “010,” “011,” “100,” “101,” “110,” and “111” of three bits, or one of other values of another number of multiple bits. A cell that has the ability to store multiple bits is sometimes called a multi-level cell (or multi-state cell).

Memory device 100 can include a non-volatile memory device, and memory cells 103 can include non-volatile memory cells, such that memory cells 103 can retain information stored thereon when power (e.g., Vcc, Vss, or both) is disconnected from memory device 100. For example, memory device 100 can be a flash memory device, such as a NAND flash or a NOR flash memory device, or another kind of memory device, such as a variable resistance memory device (e.g., a phase change or resistive RAM device).

Memory device 100 can include a memory device where memory cells 103 can be physically located in multiple levels on the same device, such that some of memory cells 103 can be stacked over some other memory cells 103 in multiple levels over a substrate (e.g., a semiconductor substrate) of memory device 100. Memory device 100 can include isolation trenches that electrically separate components within a semiconductor substrate. Isolation trenches may include configurations described in more detail below.

One of ordinary skill in the art will recognize that memory device 100 may include other elements, several of which are not shown in FIG. 1, so as not to obscure the example embodiments described herein.

FIG. 2 shows a semiconductor memory device 200. The memory device 200 includes a memory array 230 and a circuit 250 adjacent to the memory array 230. In one example, the circuit 250 is electrically connected to the memory array 230. In one example, the circuit 250 includes peripheral circuitry that operates aspects of memory operations. One example of memory operations includes, but is not limited to, memory erase operations. In one example, circuit 250 operates at voltages high enough to erase blocks of memory in the memory array 230, or selected memory cells in the memory array 230.

The memory array 230 includes rows 234 and columns 232. Memory cells, memory strings, or other memory storage devices 236 are located at intersections of rows 234 and columns 236. In one example the memory device 230 includes NAND memory. In one example the memory device 230 includes vertical NAND memory strings.

In one example, the circuit 250 includes rows 204 and columns 202. The columns 202 are separated by a number of isolation trenches 208 that are described in more detail below. One or more device components 206 are located adjacent to intersections between rows 204 and columns 202. Examples of device components include, but are not limited to, transistor source/drain contacts. In one example, the rows 204 operate transistor gates that operate between source/drain regions in the columns 202 to form transistors in the circuit 250. In one example, components 206, such as transistor sources of the circuit 250 are coupled to a source plate 240 (illustrated in block diagram form). In one example rows 204 of the circuit 250 are coupled to data lines in the memory array 230.

In one example, the memory array 230 is separated from the circuit 250 by a second isolation trench 220. Although the second isolation trench 220 is shown completely surrounding a perimeter of circuit 250, the invention is not so limited. A partial second isolation trench 220 may also be used. Examples of second isolation trench 220 are discussed in more detail below.

In one example, the memory array 230 and the circuit 250 are formed on pitch with one another. A pitch 209 between columns 202 is shown. In one example a pitch between columns 232 in the memory array is the same as the pitch 209 between columns 202 in the circuit 250. In one example, other components are formed on pitch between the memory array 230 and the circuit 250. For example, rows 234 and rows 204 may be formed on pitch between the memory array 230 and the circuit 250. In another example, isolation trenches 208 are formed on pitch between the memory array 230 and the circuit 250. Some or all of these example components (rows, columns, isolation trenches) may be formed on pitch between the memory array 230 and the circuit 250. Although these components are listed as examples, other components may also be on pitch between the memory array 230 and the circuit 250.

One technical challenge in semiconductor device fabrication is how to reduce a number of fabrication steps, such as masking, etching, depositing, implanting, etc. Another challenge is how to scale components smaller in order to fit more components within a given area of a semiconductor die. By using components that are on pitch, and adapting them to different needs (such as different voltage needs for a peripheral circuit versus a memory array), fabrication of semiconductor memory devices becomes more efficient and device density within a given area is improved. In one example, isolation trenches 208 are adapted to address these technical challenges.

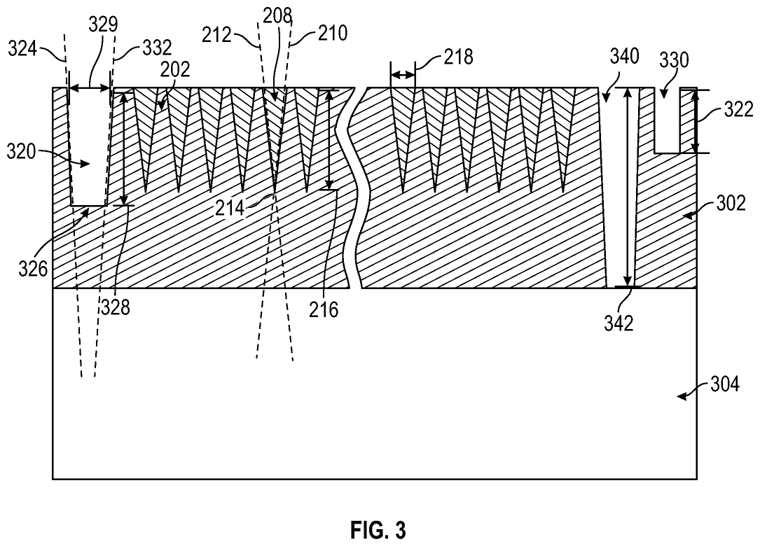

FIG. 3 shows a cross section of a portion of circuit 250 along line 252. Columns 202 are shown in cross section view as formed on fins within a semiconductor substrate 302. The number of isolation trenches 208 are shown separating the columns 202. A second isolation trench 320, a third isolation trench 330, and a fourth isolation trench 340 are shown, each with different characteristics. In one example, one or more of the isolation trenches 208, 320, 330, 340 are filled with a dielectric material such as an oxide material to provide electrical isolation between components or devices.

The third isolation trench 330 is illustrated as a standard isolation trench. It includes a depth 322. The second isolation trench 320 is shown with a second depth 328 deeper than the depth 322 of the third isolation trench 330. In one example, the second isolation trench 320 is a deep isolation trench designed to provide increased isolation in comparison to the third isolation trench 330. However, the increased depth 328 comes at a cost of increased width 329 over the third isolation trench 330. The increased width 329 and depth 328 are at least partially tied together due to etch rates within the semiconductor substrate, which is typically silicon.

In some circuit applications, such as peripheral circuitry of a memory array, it is desirable to have increased isolation capability, however, it is desirable to keep device components as small as possible in order to keep device density high. Isolation trench 208, as illustrated in FIG. 3, has a depth 216 that is deeper than third isolation trench depth 322, but not as deep as depth 328 of the second isolation trench 320. However, the width 218 of isolation trench 208 is smaller than width 329, and allows columns 202 to remain on pitch with a memory array such as memory array 230 from FIG. 2. One way to accomplish the smaller width 218 includes changing a profile of a bottom of the isolation trench 208.

The isolation trenches 208 include tapered sidewalls 210 and 212. In the example shown, the tapered sidewalls 210 and 212 intersect along a line at a trench bottom 214. The trench bottom 214 of isolation trenches 208 are pointed. In contrast, sidewalls 322 and 324 of the second isolation trench 320 do not intersect, and a bottom 326 of the second isolation trench 320 is flat. This configuration of isolation trenches 208 is provided by a shorter etch that attains depth 216 without flattening out the bottom 214 of the trenches 208.

This configuration provides increased isolation in comparison to third isolation trench 330, although less isolation that the second isolation trench 320. However, isolation trenches 208 have a smaller width 218 and allow formation on pitch with a memory array. In one example the isolation trenches 208 allow circuit 250 to operate at a high enough voltage to perform selected voltage sensitive memory operations. In one example, the isolation trenches 208 allow circuit 250 to operate up to 3.5 volts.

The fourth isolation trench 340 may be used in selected examples. In the example shown, the fourth isolation trench 340 is etched through an entire thickness of substrate 302. This provides even more electrical isolation than second isolation trench 320. In one example, fourth isolation trench 340 is used to form isolation structure 220 from FIG. 2. In one example, third isolation trench 330 is used to form isolation structure 220 from FIG. 2. In one example, where fourth isolation trench 340 is used, a second wafer 304 is coupled to the substrate 302 in a stacked wafer arrangement. In one example, where fourth isolation trench 340 is used, a through etch depth 342 may be obtained by thinning the substrate 302 from a backside after formation of fourth isolation trench 340 and filling the trench 340 with dielectric. In one example, thinning the substrate 302 includes thinning to less than 3 microns to provide through thickness depth 342.

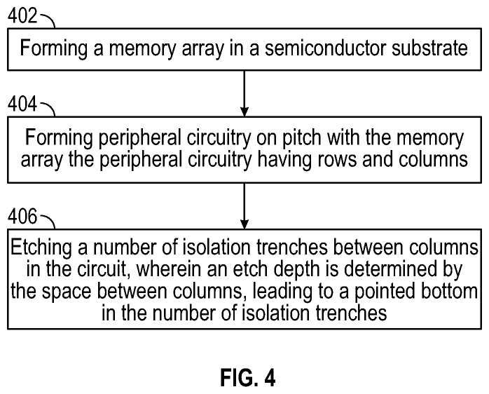

FIG. 4 shows a flow diagram of one example method of manufacture. In operation 402, a memory array is formed in a semiconductor substrate. In operation 404, peripheral circuitry is formed on pitch with the memory array. The peripheral circuitry includes rows and columns. In operation 406, a number of isolation trenches are etched between columns in the circuit, wherein an etch depth is determined by the space between columns, leading to a pointed bottom in the number of isolation trenches. In one example, etching includes plasma etching.

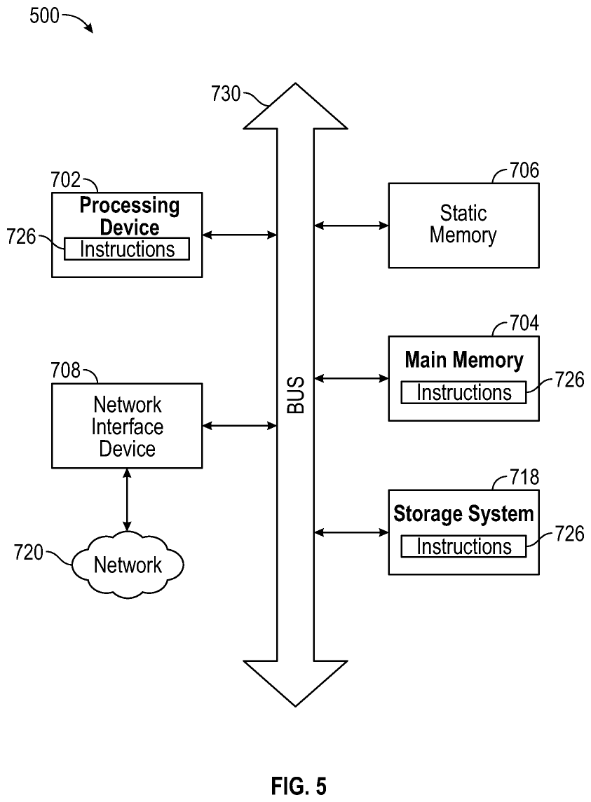

FIG. 5 illustrates a block diagram of an example machine (e.g., a host system) 500 which may include one or more transistors, memory devices and/or memory systems as described above. As discussed above, machine 500 may benefit from enhanced memory performance from use of one or more of the described transistor structures and/or memory systems, facilitating improved performance of machine 500 (as for many such machines or systems, efficient reading and writing of memory can facilitate improved performance of a processor or other components that machine, as described further below.

In alternative embodiments, the machine 500 may operate as a standalone device or may be connected (e.g., networked) to other machines. In a networked deployment, the machine 500 may operate in the capacity of a server machine, a client machine, or both in server-client network environments. In an example, the machine 500 may act as a peer machine in peer-to-peer (P2P) (or other distributed) network environment. The machine 500 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 500 may include a processing device 502 (e.g., a hardware processor, a central processing unit (CPU), a graphics processing unit (GPU), a hardware processor core, or any combination thereof, etc.), a main memory 504 (e.g., read-only memory (ROM), dynamic random-access memory (DRAM) such as synchronous DRAM (SDRAM) or Rambus DRAM (RDRAM), etc.), a static memory 506 (e.g., static random-access memory (SRAM), etc.), and a storage system 518, some or all of which may communicate with each other via a communication interface (e.g., a bus) 530. In one example, the main memory 504 includes one or more memory devices as described in examples above.

The processing device 502 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 502 can also be one or more special-purpose processing devices such as an application specific integrated circuit (ASIC), a field programmable gate array (FPGA), a digital signal processor (DSP), network processor, or the like. The processing device 502 can be configured to execute instructions 526 for performing the operations and steps discussed herein. The computer system 500 can further include a network interface device 508 to communicate over a network 520.

The storage system 518 can include a machine-readable storage medium (also known as a computer-readable medium) on which is stored one or more sets of instructions 526 or software embodying any one or more of the methodologies or functions described herein. The instructions 526 can also reside, completely or at least partially, within the main memory 504 or within the processing device 502 during execution thereof by the computer system 500, the main memory 504 and the processing device 502 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with multiple particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 500 may further include a display unit, an alphanumeric input device (e.g., a keyboard), and a user interface (UI) navigation device (e.g., a mouse). In an example, one or more of the display unit, the input device, or the UI navigation device may be a touch screen display. The machine a signal generation device (e.g., a speaker), or one or more sensors, such as a global positioning system (GPS) sensor, compass, accelerometer, or one or more other sensor. The machine 500 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 526 (e.g., software, programs, an operating system (OS), etc.) or other data are stored on the storage system 518 can be accessed by the main memory 504 for use by the processing device 502. The main memory 504 (e.g., DRAM) is typically fast, but volatile, and thus a different type of storage than the storage system 518 (e.g., an SSD), which is suitable for long-term storage, including while in an “off” condition. The instructions 526 or data in use by a user or the machine 500 are typically loaded in the main memory 504 for use by the processing device 502. When the main memory 504 is full, virtual space from the storage system 518 can be allocated to supplement the main memory 504; however, because the storage system 518 device is typically slower than the main memory 504, and write speeds are typically at least twice as slow as read speeds, use of virtual memory can greatly reduce user experience due to storage system latency (in contrast to the main memory 504, e.g., DRAM). Further, use of the storage system 518 for virtual memory can greatly reduce the usable lifespan of the storage system 518.

The instructions 524 may further be transmitted or received over a network 520 using a transmission medium via the network interface device 508 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.15 family of standards known as Wi-Fi®, IEEE 802.16 family of standards known as WiMax®), IEEE 802.15.4 family of standards, peer-to-peer (P2P) networks, among others. In an example, the network interface device 508 may include one or more physical jacks (e.g., Ethernet, coaxial, or phone jacks) or one or more antennas to connect to the network 520. In an example, the network interface device 508 may include multiple antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 500, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” (in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” is used herein to refer generally to any structure on which integrated circuits are formed, and also to such structures during various stages of integrated circuit fabrication. The term “substrate” is used to refer to either a wafer, or other structures which support or connect to other components, such as memory die or portions thereof. Thus, the term “substrate” embraces, for example, circuit or “PC” boards, interposers, and other organic or non-organic supporting structures (which in some cases may also contain active or passive components). The following detailed description is, therefore, not to be taken in a limiting sense, and the scope of the various embodiments is defined only by the appended claims, along with the full scope of equivalents to which such claims are entitled.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMS), read only memories (ROMs), and the like.

To better illustrate the method and apparatuses disclosed herein, a non-limiting list of embodiments is provided here:

Example 1 is a semiconductor memory device. The device includes a memory array formed in a semiconductor substrate, a circuit coupled to the memory array, the circuit having rows and columns, and a number of isolation trenches between columns in the circuit, wherein the number of isolation trenches include tapered sidewalls that intersect along a line at a trench bottom.

In Example 2, the semiconductor memory device of Example 1 optionally further includes a second trench at least partially surrounding a perimeter of circuit wherein sidewalls of the second trench do not intersect.

In Example 3, the semiconductor memory device of any one of Examples 1-2 optionally includes wherein a depth of the number of isolation trenches is less than a depth of the second trench.

In Example 4, the semiconductor memory device of any one of Examples 1-3 optionally further includes a third trench, wherein a depth of the number of isolation trenches is between the depth of the second trench and a depth of the third trench.

In Example 5, the semiconductor memory device of any one of Examples 1-4 optionally includes wherein the circuit coupled to the memory array is formed in a first wafer, and wherein the first wafer is coupled to a second wafer in a stacked wafer arrangement.

In Example 6, the semiconductor memory device of any one of Examples 1-5 optionally further includes a through etch isolation at least partially surrounding a perimeter of circuit in the first wafer.

In Example 7, the semiconductor memory device of any one of Examples 1-6 optionally includes wherein the circuit is formed on pitch with the memory array.

In Example 8, the semiconductor memory device of any one of Examples 1-7 optionally includes wherein the number of isolation trenches have an aspect ratio of approximately 4 to 1.

Example 9 is a semiconductor memory device. The device includes a memory array formed in a semiconductor substrate, a peripheral circuitry configured for memory operations including an erase operation, the peripheral circuitry having rows and columns, and a number of isolation trenches between columns in the peripheral circuitry, wherein the number of isolation trenches include tapered sidewalls that intersect along a line at a trench bottom.

In Example 10, the semiconductor memory device of Example 9 optionally includes wherein the peripheral circuitry includes a row coupled to a source plate.

In Example 11, the semiconductor memory device of any one of Examples 9-10 optionally includes wherein the peripheral circuitry includes a row coupled to data lines in the memory array.

In Example 12, the semiconductor memory device of any one of Examples 9-11 optionally includes wherein the number of isolation trenches are on pitch with the memory array.

In Example 13, the semiconductor memory device of any one of Examples 9-12 optionally includes wherein the memory array includes a NAND memory array.

In Example 14, the semiconductor memory device of any one of Examples 9-13 optionally includes wherein the memory array includes vertical NAND memory strings.

In Example 15, the semiconductor memory device of any one of Examples 9-14 optionally includes wherein the peripheral circuitry operates at 3.5 volts or less.

Example 16 is a method. The method includes forming a memory array in a semiconductor substrate, forming peripheral circuitry on pitch with the memory array the peripheral circuitry having rows and columns, and etching a number of isolation trenches between columns in the circuit, wherein an etch depth is determined by the space between columns, leading to a pointed bottom in the number of isolation trenches.

In Example 17, the method of Example 16 optionally includes wherein etching a number of isolation trenches includes plasma etching.

In Example 18, the method of any one of Examples 16-17 optionally further includes forming second trenches on at least a portion of a perimeter of the peripheral circuitry, the second trenches having a depth deeper than the number of isolation trenches.

In Example 19, the method of any one of Examples 16-18 optionally includes wherein forming peripheral circuitry includes forming memory erase circuitry.

In Example 20, the method of any one of Examples 16-19 optionally further includes thinning the semiconductor substrate to less than 3 microns.

In Example 21, the method of any one of Examples 16-20 optionally further includes through etching around at least a portion of a perimeter of the peripheral circuitry.

In Example 22, the method of any one of Examples 16-21 optionally further includes coupling the semiconductor substrate to a second semiconductor substrate.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A semiconductor memory device, comprising:
a memory array formed in a semiconductor substrate;
a circuit coupled to the memory array, the circuit having rows and columns; and
a number of isolation trenches between columns in the circuit, wherein the number of isolation trenches include tapered sidewalls that intersect along a line at a trench bottom.

2. The semiconductor memory device of claim 1, further including a second trench at least partially surrounding a perimeter of circuit wherein sidewalls of the second trench do not intersect.

3. The semiconductor memory device of claim 2, wherein a depth of the number of isolation trenches is less than a depth of the second trench.

4. The semiconductor memory device of claim 3, further including a third trench, wherein a depth of the number of isolation trenches is between the depth of the second trench and a depth of the third trench.

5. The semiconductor memory device of claim 1, wherein the circuit coupled to the memory array is formed in a first wafer, and wherein the first wafer is coupled to a second wafer in a stacked wafer arrangement.

6. The semiconductor memory device of claim 5, further including a through etch isolation at least partially surrounding a perimeter of circuit in the first wafer.

7. The semiconductor memory device of claim 1, wherein the circuit is formed on pitch with the memory array.

8. The semiconductor memory device of claim 1, wherein the number of isolation trenches have an aspect ratio of approximately 4 to 1.

9. A semiconductor memory device, comprising:
a memory array formed in a semiconductor substrate;
a peripheral circuitry configured for memory operations including an erase operation, the peripheral circuitry having rows and columns; and
a number of isolation trenches between columns in the peripheral circuitry, wherein the number of isolation trenches include tapered sidewalls that intersect along a line at a trench bottom.

10. The semiconductor memory device of claim 9, wherein the peripheral circuitry includes a row coupled to a source plate.

11. The semiconductor memory device of claim 10, wherein the peripheral circuitry includes a row coupled to data lines in the memory array.

12. The semiconductor memory device of claim 9, wherein the number of isolation trenches are on pitch with the memory array.

13. The semiconductor memory device of claim 9, wherein the memory array includes a NAND memory array.

14. The semiconductor memory device of claim 9, wherein the memory array includes vertical NAND memory strings.

15. The semiconductor memory device of claim 9, wherein the peripheral circuitry operates at 3.5 volts or less.

16. A method, comprising:
forming a memory array in a semiconductor substrate;
forming peripheral circuitry on pitch with the memory array the peripheral circuitry having rows and columns; and
etching a number of isolation trenches between columns in the circuit, wherein an etch depth is determined by the space between columns, leading to a pointed bottom in the number of isolation trenches.

17. The method of claim 16, wherein etching a number of isolation trenches includes plasma etching.

18. The method of claim 16, further including forming second trenches on at least a portion of a perimeter of the peripheral circuitry, the second trenches having a depth deeper than the number of isolation trenches.

19. The method of claim 16, wherein forming peripheral circuitry includes forming memory erase circuitry.

20. The method of claim 16, further including thinning the semiconductor substrate to less than 3 microns.

21. The method of claim 20, further including through etching around at least a portion of a perimeter of the peripheral circuitry.

22. The method of claim 21, further including coupling the semiconductor substrate to a second semiconductor substrate.
